(19) United States
(12) Patent Application Publication
(10) Pub. No.: US 2026/0333602 A1
(43) Pub. Date: Oct. 22, 2026

(54) SEALING SENSOR COVER

(71) Applicant: DANA ITALIA S.R.L., Arco (IT)

(72) Inventors: Simone TRAPLETTI, Riva del Garda (IT); Gianluca TERRASI, Arco (IT); Cristina COCIANCICH, Arco (IT); Roberto RAMPAZZO, Trento (IT)

(21) Appl. No.: 19/184,866

(22) Filed: Apr. 21, 2025

(51) Int. Cl. H05K 5/03; B62D 6/08

(52) U.S. Cl. CPC H05K 5/03; B62D 6/08

(57) ABSTRACT

Disclosed herein are systems and methods for a sealing sensor cover of a steering system. The sealing sensor cover may be arranged between a sensor and a kingpin bearing. The steering system may further include one or more sealing rings integral with the sealing sensor cover.

### TECHNICAL FIELD

The present description relates generally to a sealing sensor cover for sealing a sensor from fluid.

### BACKGROUND AND SUMMARY

A steering sensor of a vehicle may detect a position of a steering wheel. The steering sensor may be coupled to a kingpin bearing. Conventionally, the sensor may be protected from lubricant (e.g., oil) of the bearing by a metal cover. An O-ring may be used to form a seal between the metal cover and the sensor. By preventing lubricant from flowing from the bearing to the sensor, degradation to the bearing caused by lubricant loss may be avoided. Preventing lubricant from flowing to the sensor may also reduce and/or avoid degradation of the sensor due to fluid interference with operation of the sensor. However, such a conventional sealing method may demand precise machining of the metal cover, increasing resource demand and a likelihood of assembly error and/or degradation of the seal leading to leakage of lubricant out of the bearing.

Embodiments are disclosed herein of a sealing sensor cover that addresses at least some of the issues described above. For example, a steering system may comprise a sealing sensor cover arranged between a sensor and a kingpin bearing. The steering system may further comprise one or more sealing rings integral with the sealing sensor cover. In this way, integration of the sealing rings into the sealing sensor cover may reduce a number of parts demanded for assembly within a steering system and eliminate precise metal machining, thereby decreasing complexity (e.g., quantity of interconnected components and manufacturing/assembly operations) and resource demand of the steering system. Further, incorporating the sealing rings into the sealing sensor cover eliminates interfaces in conventional systems wherethrough lubricant may leak between the metal cover and the O-ring due to potential for mistakes in manufacturing and assembly (e.g., O-ring misaligned with the metal cover or omitted) and/or degradation during operation. Thus, the sealing sensor cover may provide a sealing means for retaining lubricant fluid in a bearing adjacent to a steering sensor that is simpler and more effective in maintaining the seal compared to other sealing systems such as those including a metal cover and a separate (e.g., non-integral) O-ring.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

FIG. 1 shows a schematic of a vehicle including a steering system.

FIG. 2 shows the steering system of the vehicle.

FIG. 3 shows an enlarged view of a portion of the steering system, including a sealing sensor cover.

FIG. 4 shows a cross sectional view of the sealing sensor cover

FIG. 5 shows a perspective view of the sealing sensor cover.

FIG. 6 shows a flowchart of a method for manufacturing the steering system.

FIG. 7 shows a flowchart of a method for operating a steering system comprising the sealing sensor cover.

### DETAILED DESCRIPTION

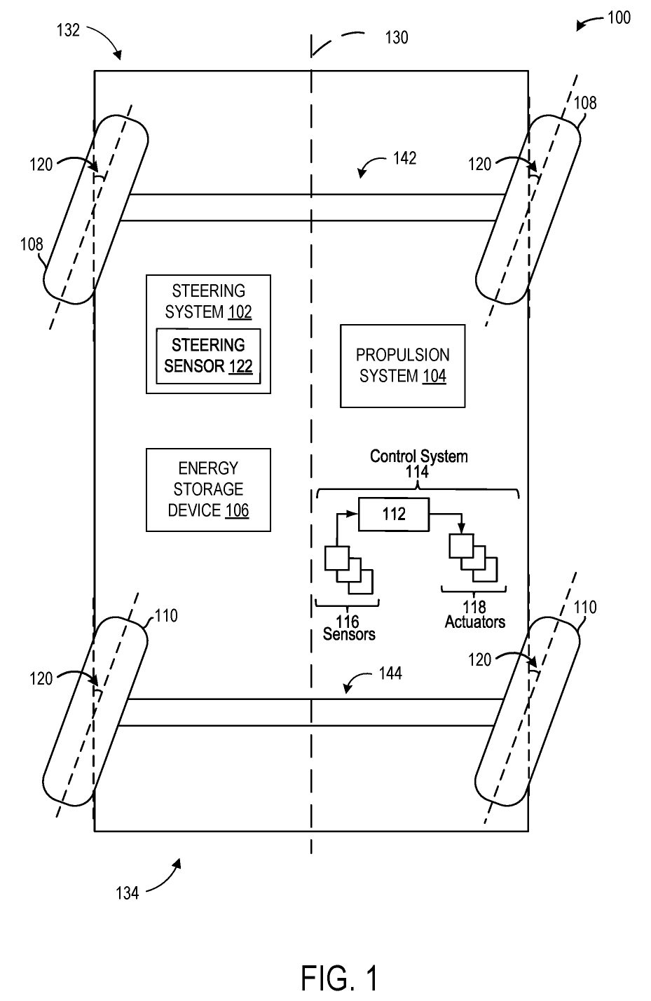

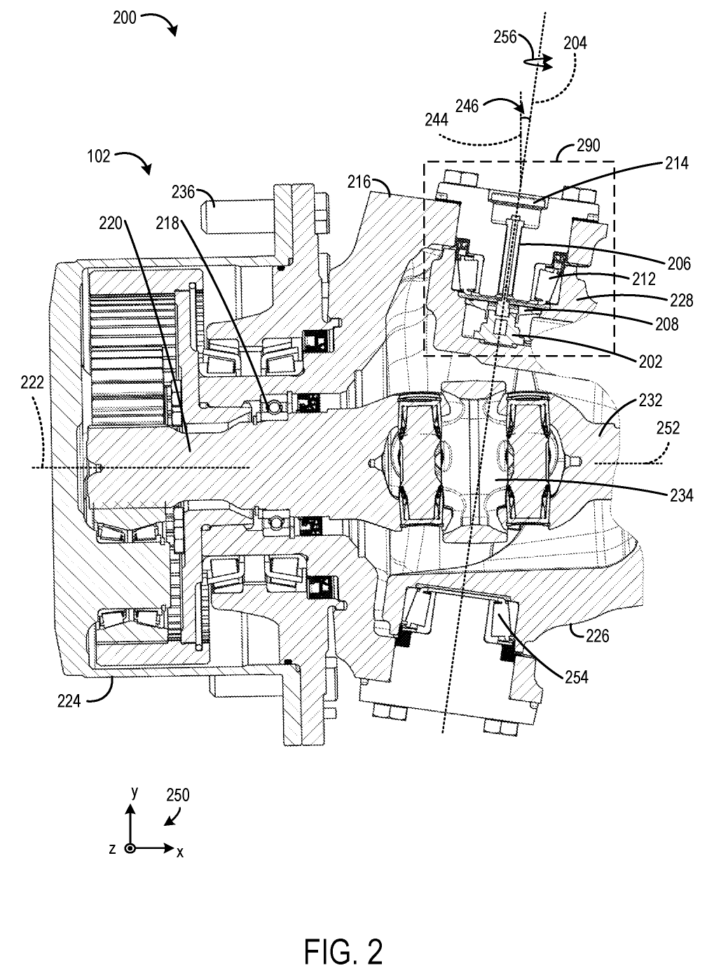

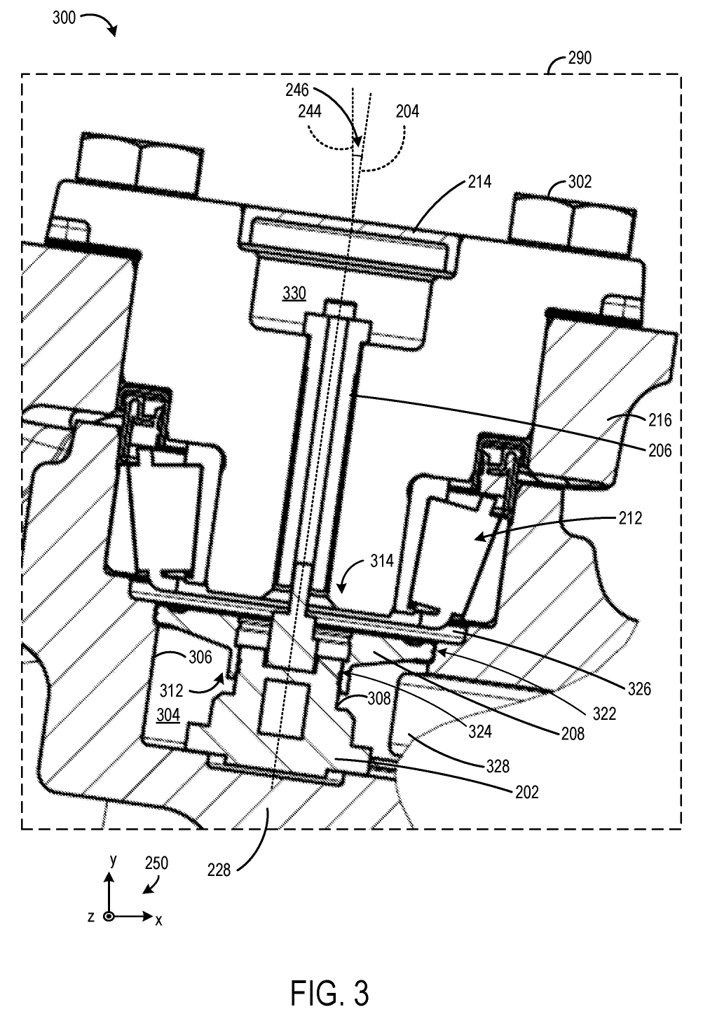

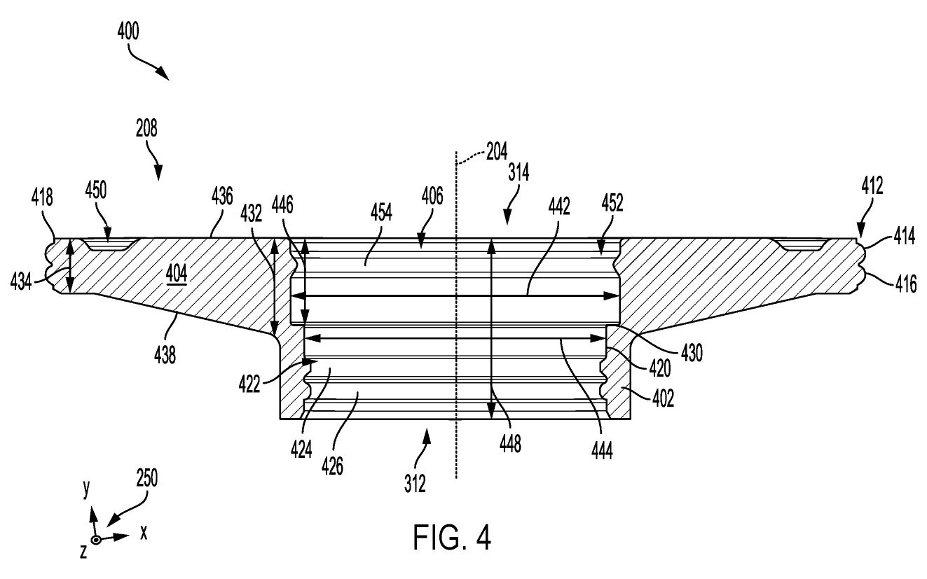

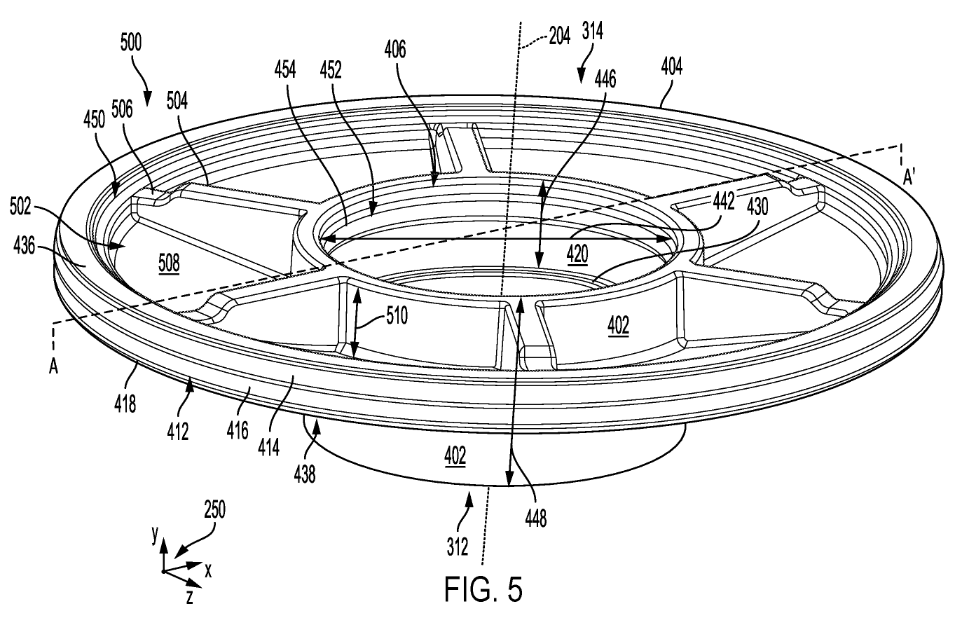

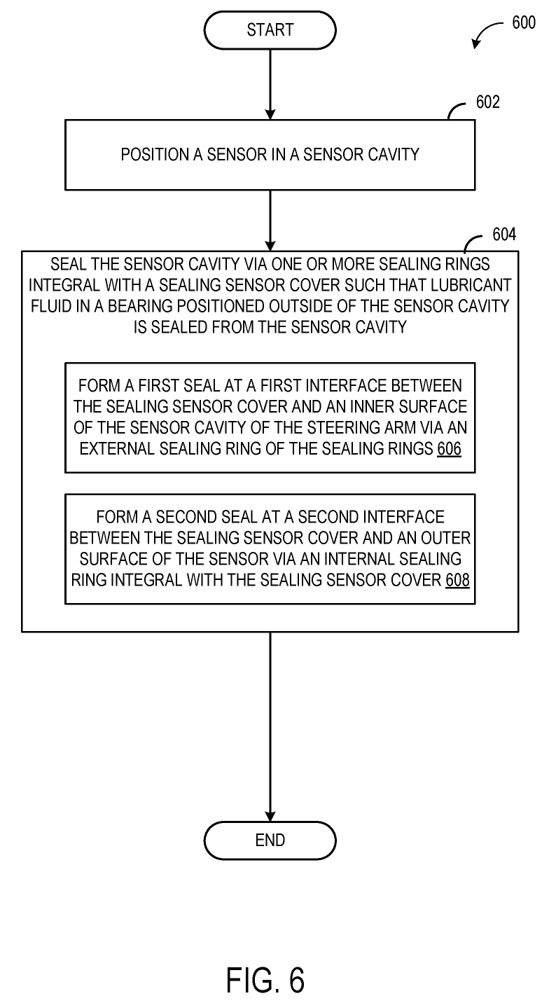

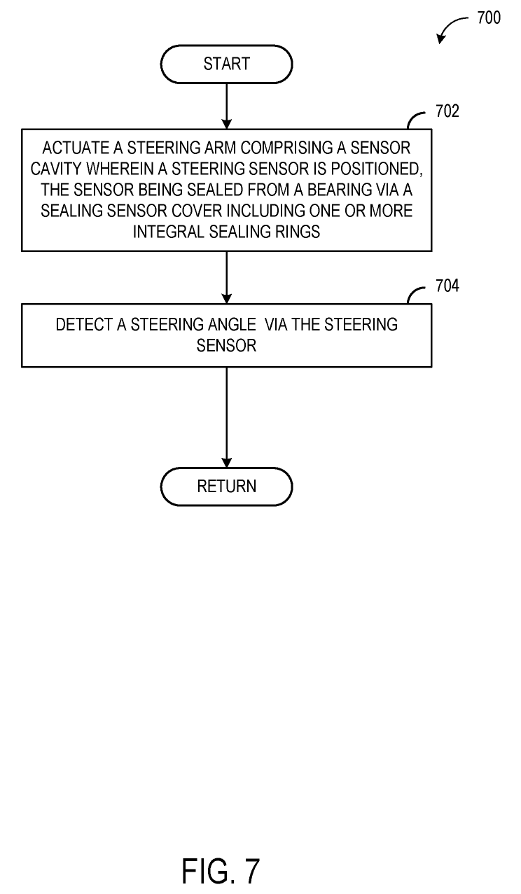

The following description relates to systems and methods for a steering system comprising a sealing sensor cover. The steering system, an example of which is provided in FIG. 2, may be included in a vehicle such as the vehicle of FIG. 1. The steering system may include a knuckle that is pivotably coupled to a steering arm via a kingpin. The sealing sensor cover may seal to a sensor (e.g., steering sensor) and an inner surface of a steering arm as shown in FIG. 3 such that lubricant fluid of a bearing of the kingpin is prevented from flowing into a sensor cavity in which the sensor is positioned. In this way, the sealing sensor cover may retain the lubricant fluid in the bearing, reducing degradation to the bearing. The sealing sensor cover is further shown in greater detail in FIGS. 4 and 5. A method for manufacturing the steering system is shown as a flowchart in FIG. 6. The method includes forming seals between the sealing sensor cover, the sensor, and the sensor cavity without additional sealing components (e.g., one or more O-rings). Instead of such additional components, the sealing sensor cover includes integral sealing rings which form the seals when pressed against the surfaces of the sensor and the sensor cavity. FIG. 7 shows a flowchart of a method for operating the steering system.

It is to be understood that the specific assemblies and systems illustrated in the attached drawings, and described in the following specification are exemplary embodiments of the inventive concepts defined herein. For purposes of discussion, the drawings are described collectively. Thus, like elements may be commonly referred to herein with like reference numerals and may not be re-introduced.

Turning to FIG. 1, a schematic of a vehicle 100 is shown. The vehicle 100 may have a longitudinal axis 130. The vehicle 100 may also have a front side 132 and a rear side 134. The vehicle 100 may include a first axle assembly 142 and a second axle assembly 144. The first axle assembly 142 may be configured to drive a first set of wheels 108, and the second axle assembly 144 may be configured to drive a second set of wheels 110. In one example, the first axle assembly 142 is arranged near the front side 132 of the vehicle 100 and thereby comprises a front axle, and the second axle assembly 144 is arranged near rear side 134 of the vehicle 100 and thereby comprises a rear axle. The second axle assembly 144 may be closer to the rear side 134 compared to the front side 132. The embodiment shown in FIG. 1 may have a front wheel drivetrain with front-wheel drive (FWD) capabilities. Rotational energy generated by movers of the vehicle 100, such as a propulsion system 104, may be delivered to the first axle assembly 142 at the front side 132 of the vehicle 100, thereby propelling the vehicle 100. The vehicle 100 is shown in a four-wheel drive configuration, although other configurations are possible. For example, the vehicle 100 may include a rear-wheel drive (RWD), where rotational energy is delivered from the propulsion system 104 to the second axle assembly 144 at the rear side 134 of the vehicle, or an all-wheel drive configuration (AWD) where rotational energy is delivered from the propulsion system 104 to both the first axle assembly 142 and to the second axle assembly 144. Further, the vehicle 100 may include one or more tandem axle assemblies. As such, the vehicle 100 may have other configurations without departing from the scope of this disclosure, and the configuration shown in FIG. 1 is provided for illustration, not limitation.

The propulsion system 104 may include an engine (e.g., internal combustion engine (ICE)) and/or one or more electric motors. Thus, the vehicle 100 may be an electric vehicle, a hybrid vehicle, or an ICE vehicle. The propulsion system 104 may further include a transmission configured to deliver mechanical energy from the ICE and/or electric motor(s) to the wheels 108. The vehicle 100 may further include an energy storage device 106 comprising one or more batteries and/or capacitors. The energy storage device 106 may be configured to electrically power the electric motor(s), if included, and/or one or more auxiliary vehicle systems such as lights, radio, climate control, navigation, etc. A steering system 102 of the vehicle 100 may be configured to adjust an angle of one or more of the first set of wheels 108 and the second set of wheels 110 according to configuration of the vehicle 100 and user input order to guide the direction of propulsion of the vehicle 100. For example, the vehicle 100 may travel in a linear direction when a wheel angle of the first set of wheels 108 and the second set of wheels 110 is equal to zero (e.g., parallel to the longitudinal axis 130). An operator of the vehicle 100 may rotate a steering wheel in order to adjust an angle of the first set of wheels 108 and/or the second set of wheels 110 to a non-zero angle to turn the vehicle 100. For example, the first set of wheels 108 and/or the second set of wheels 110 may have a first wheel angle 120, with respect to the longitudinal axis 130, to turn the vehicle 100 in a rightward direction.

The vehicle 100 may include a control system 114, comprising a controller 112, one or more sensors 116, and one or more actuators 118. The controller 112 may include a processing unit, and memory, such as non-volatile memory. The controller 112 may be communicatively coupled to the sensors 116 and the actuators 118. For example, the sensors 116 may send electrical signals to the controller 112, and the controller 112 may respond to such sensor feedback by sending command signals to actuate the actuators 118. The actuators 118 may include the ICE and/or electric motor(s). The sensors 116 may include a wheel speed sensor, temperature sensors, pressure sensors, etc.

The sensors 116 may further include a steering sensor 122 configured to detect an angle of one of the wheels 108. In doing so, the steering sensor 122 may measure a steering angle of a knuckle of the steering system 102 relative to a steering arm of the steering system 102 that is pivotably coupled to the knuckle via a kingpin, as described further below. Additionally, as described below with reference to FIGS. 2-7, a sealing sensor cover may fluidly separate the steering sensor 122 from the kingpin bearing, which may prevent lubricant fluid (e.g., oil) of the kingpin bearing from leaking toward the steering sensor, thereby reducing degradation to the kingpin bearing caused by lubricant loss, and consequently reducing issues with steering actuation. The sealing sensor cover may be self-sealing such that the sealing sensor cover may seal at a first interface to the steering arm and at a second interface to the steering sensor 122 without any other sealing components, such as O-rings. Thus, system complexity and resource demand may be reduced compared to other systems comprising a cover which is installed with one or more O-rings to form the seals. Although described herein as sealing a steering sensor 122 from fluid of a kingpin bearing, the sealing sensor cover of the present disclosure may be used to seal sensors for different purposes than sensing a steering angle.

Turning to FIG. 2, the steering system 102 is shown in a cross sectional view 200. A set of reference axes 250 are provided in FIG. 2, as well as FIGS. 3-5 which are discussed below for comparison of the orientations shown therein. The reference axes 250 include an x-axis, a y-axis, and a z-axis. The y-axis may be a vertical axis, with respect to gravity, and the z- and x-axes may be horizontal axes, in one example. However, other orientations are possible.

A wheel hub 224 may be rotationally coupled to an axle shaft 232 which receives torque from a propulsion system (e.g., propulsion system 104 of the vehicle 100 of FIG. 1). For example, an engine and/or motor(s) may drive rotation of a driveshaft coupled to the axle shaft 232 via a differential. The axle shaft 232 may be included in the first axle assembly 142 or the second axle assembly 144 of FIG. 1. The wheel hub 224 may be fixedly coupled to a first wheel (e.g., one of the wheels 108 of FIG. 1) via fasteners 236 (e.g., bolts). A wheel hub bearing 218 may allow rotation of a wheel hub shaft 220 relative to a knuckle 216 about a rotational axis 222. The rotational axis 222 may extend centrally through the wheel hub shaft 220, and the wheel hub 224. Thus, the wheel coupled to the wheel hub 224 may rotate along with the wheel hub 224 about the rotational axis 222. The wheel hub shaft 220 may receive torque from the axle shaft 232 via a joint 234 (e.g., continuous velocity joint, universal joint, or the like) that allows various angles therebetween. That is, the joint 234 may allow transmission of torque between the axle shaft 232 and the wheel hub shaft 220 regardless of an angle between the rotational axis 222 and a second rotational axis 252 of the axle shaft 232 which changes as a steering angle of the first wheel is adjusted (e.g., by the user rotating a steering wheel).

A steering sensor 202 configured to measure the steering angle is mounted coaxially with a steering axis 204. The steering sensor 202 may be an example of the steering sensor 122 of FIG. 1. The steering sensor 202 may be fixedly attached to a kingpin 206 extending along (e.g., parallel to) the steering axis 204. The kingpin 206 may be fixedly attached to the knuckle 216, such as via one or more fasteners. Thus, the steering sensor 202 may be fixedly attached to the knuckle 216 via the kingpin 206. The knuckle 216 may be rotatable about the steering axis 204 against a steering arm 228. In this way, the knuckle 216 may pivot around the steering axis 204 into and out of the page, as indicated by an arrow 256. A kingpin bearing 212 may allow relatively smooth rotational movement between the knuckle 216 and the steering arm 228 about the steering axis 204. The steering angle measured by the steering sensor 202 is related to the relative angular position of the knuckle 216 and the steering arm 228 with respect to the steering axis 204. The steering arm 228 may be mechanically coupled to a steering wheel such that rotation of the steering wheel (e.g., via manual intervention of the user and/or automated rotation such as in a self-driving mode) actuates the steering arm 228 in order to change the steering angle.

A kingpin inclination angle 246, also known as the steering axis inclination, between the steering axis 204 and a vertical axis 244 (e.g., parallel with the y-axis and a direction of gravity) may be a non-zero angle (e.g., approximately 4-10 degrees). The steering axis 204 being offset from the vertical axis 244 by the kingpin inclination angle 246 may result in a tendency of the steering wheel to return to a center (e.g., zero-degree rotation position) during vehicle propulsion. Thus, the steering axis 204 may not be normal to a horizontal axis and/or the rotational axis 222.

A steering axle 226 may couple to the knuckle 216 via a second bearing 254, allowing relative rotational motion between the steering axle 226 and the knuckle 216 about the steering axis 204. The steering axle 226 may couple in a similar manner (e.g., via a bearing and a knuckle) to a second wheel hub laterally opposite the wheel hub 224 across the vehicle comprising the steering system 102 (e.g., vehicle 100 of FIG. 1). For example, the steering axle 226 may extend approximately parallel to the axle shaft 232 to the second wheel hub which is rotationally fixed to a second wheel. The steering axle 226 may translate rotational motion of the knuckle 216, the wheel hub 224, and consequently the first wheel (which is coupled to the wheel hub 224 via the fasteners 236) about the steering axis 204 to the second wheel hub so as to control steering of both of the first wheel and the second wheel via actuation of the steering arm 228.

Upon rotation of the knuckle 216 relative to the steering arm 228 about the steering axis 204, the steering sensor 202 may rotate as well. For example, the steering sensor 202 may follow an arc pathway centered around the steering axis 204 in a plane perpendicular to the steering axis 204. In this way, the steering sensor 202 may be configured to measure the steering angle about the steering axis 204 of the knuckle 216 relative to the steering arm 228, as described above. The steering sensor 202 may be electrically coupled to a power source (e.g., energy storage device 106 of FIG. 1) and communicatively coupled to a processing unit (e.g., of the controller 112 of FIG. 1). The steering sensor 202 may transmit electrical signals indicating the steering angle to the processing unit which may react automatically to the electrical signals by sending command signals to one or more actuators, as described above.

A sealing sensor cover 208 may be interposed between the kingpin bearing 212 and the steering sensor 202 to prevent lubricant fluid from leaking towards the steering sensor 202. The sealing sensor cover 208 may seal to the steering sensor 202 without additional components involved in forming the seal. Thus, the sealing sensor cover 208 may retain fluid within the kingpin bearing 212, preventing lubricant loss causing degradation to the kingpin bearing 212 which may in turn hinder steering function. Preventing lubricant from flowing to the steering sensor 202 may also reduce and/or avoid degradation of the steering sensor 202 due to fluid interference with operation of the steering sensor 202.

Now referencing FIG. 3, an enlarged view 300 of a portion 290 of FIG. 2 is shown for greater detail. As described above, the knuckle 216 is fixedly coupled to the kingpin 206 (e.g., via one or more fasteners 302), and the steering sensor 202 is fixedly coupled to the steering arm 228 which rotates freely about the steering axis 204 relative to the knuckle 216 due to the kingpin bearing 212. More specifically, the steering sensor 202 may be positioned within a sensor cavity 304 of the steering arm 228. Such a position where the steering sensor 202 is embedded within the steering arm 228 may prevent external agents (e.g., fluids, rocks, mud, etc.) from degrading and/or hindering function of the steering sensor 202. A cup 214 may further protect the kingpin bearing 212 from such external agents. For example, the cup 214 may be positioned so as to enclose a pin cavity 330 where an end of the kingpin 206 is positioned. The cup 214 may be a removable cover for the pin cavity 330. The cup 214 may fit into the pin cavity 330 via snap-fit, interference fit, or the like. The kingpin 206 may extend between the pin cavity 330 and the sensor cavity 304. The kingpin 206 may be circumferentially surrounded by a kingpin housing 326. The kingpin 206 and the kingpin housing 326 may be concentrically positioned around the steering axis 204.

A channel 328 may extend from the sensor cavity 304. The channel 328 may protect a cable of the steering sensor 202. The steering sensor 202 may transmit signals to the controller 112 of FIG. 1 via the cable. Sealing the sensor cavity 304 from lubricant leaking from the kingpin bearing 212 may prevent degradation to the steering sensor 202 and the cable extending therefrom through the channel 328.

The sensor cavity 304 may be sealed from the kingpin bearing 212 by the sealing sensor cover 208 to prevent lubricant fluid of the kingpin bearing 212 from being lost to the sensor cavity 304. Such lubricant loss may cause degradation to the kingpin bearing 212, thereby impeding the steering function. Conventionally, a metal cover and one or more O-rings may be demanded to form a seal between the kingpin bearing 212 and the sensor cavity 304. However, the sealing sensor cover 208 of the present disclosure may form a seal between the steering sensor 202 and the kingpin bearing 212 without additional components such as an O-ring. For example, the sealing sensor cover 208 may include integral sealing rings, as described further below.

The sealing sensor cover 208 may seal a first interface 322 between the sealing sensor cover 208 and an inner surface 306 of the sensor cavity 304. The inner surface 306 may circumferentially surround the steering sensor 202. The inner surface 306 may further be spaced away from the steering sensor 202 such that the volume of the sensor cavity 304 not occupied by the steering sensor 202 is hollow (e.g., air filled). Without the sealing sensor cover 208, lubricant fluid may leak from the kingpin bearing 212 into the hollow area of the sensor cavity 304. The seal formed at the first interface 322 may prevent fluid from leaking between the inner surface 306 and the sealing sensor cover 208 to the hollow area of the sensor cavity 304. The inner surface 306 may be cylindrical. Thus, the first interface 322 between the sealing sensor cover 208 and the inner surface 306 may be circular. Further, the sealing sensor cover 208 may be coaxially positioned with the steering sensor 202 along the steering axis 204.

The sealing sensor cover 208 may further seal a second interface 324 between the sealing sensor cover 208 and an outer surface 308 of the steering sensor 202. The sealing sensor cover 208 may circumferentially surround the outer surface 308 and be in face-sharing contact therewith. In this way, the sealing sensor cover 208 may be radially interposed between the outer surface 308 of the steering sensor 202 and the inner surface 306 of the sensor cavity 304.

The sealing sensor cover 208 may extend along the steering axis 204 between a sensor end 312 in face-sharing contact with the steering sensor 202 and a bearing end 314 in face-sharing contact with the kingpin bearing 212. In this way, the sealing sensor cover 208 may be coaxially positioned with the kingpin 206 and the steering sensor 202. The first interface 322 may be proximate to the bearing end 314 and the second interface may be proximate to the sensor end 312. The sealing sensor cover 208 is described in greater detail below with reference to FIGS. 4 and 5.

Turning to FIG. 4, a cross sectional view 400 of the sealing sensor cover 208 is shown. The sealing sensor cover 208 may be constructed of a flexible material. The flexible material may be rubber, as one example. In other examples, the flexible material may be silicone, plastic (e.g., elastomer), or the like. In some examples, the flexible material may include a blend of two or more of rubber, silicone, plastic, and the like. In at least some examples, the entire sealing sensor cover 208 is constructed of the flexible material. That is, the sealing sensor cover 208 may be constructed of the flexible material, and no other materials. For example, the sealing sensor cover 208 may not include an inflexible material (e.g., metal, ceramic, polyvinyl chloride and other brittle plastics, and the like) in addition to the flexible material. Further, the sealing sensor cover 208 may not include any metal, in at least some examples. However, in other examples, there may be inflexible material embedded within the flexible material for structural support. The structural support provided by the inflexible material, if included, may reduce a likelihood of degradation of the flexible material, such as fracturing, cracking, snapping, tearing, and the like of the flexible material. For example, the flexible material may be applied as a coating to the inflexible material. Alternatively, the inflexible material may be inserted into receptacles (e.g., recesses, through-holes, blind holes, etc.) of the flexible material proximate to areas where stress may concentrate (e.g., corners, etc.). Due to elastic properties of the flexible material, tolerances of machining the sealing sensor cover 208 may be increased compared to a cover constructed entirely of an inflexible material such as a metal. That is, precision of machining may be relaxed due to the flexibility of the flexible material, reducing difficulty of manufacturing and a likelihood of an inadequate fit with the sensor leading to an ineffective seal (e.g., allowing fluid to leak through the seal).

The sealing sensor cover 208 may include a cylindrical portion 402 and a disc portion 404 extending radially outward therefrom. The disc portion 404 may taper radially outwards from a first axial thickness 432 to a second axial thickness 434 smaller than the first axial thickness 432. The tapered shape of the disc portion 404 may result in a bearing side surface 436 of the disc portion 404 (e.g., at the bearing end 314) being non-parallel to a sensor side surface 438 of the disc portion 404. For example, the bearing side surface 436 may be normal to the steering axis 204. The sensor side surface 438 may be at a non-zero angle with both the steering axis 204 and the bearing side surface 436. The bearing side surface 436 may include various surface features 450, as described below with reference to FIG. 5, such that the bearing side surface 436 is not flat. The tapered shape of the disc portion 404 may minimize a volume of the sealing sensor cover 208 while maintaining adequate mechanical characteristics at the integral intersection between the cylindrical portion 402 and the disc portion 404. The tapered shape of the disc portion 404 may further allow the sealing sensor cover 208 to accommodate positioning of the channel 328 as shown in FIG. 3.

A central through-hole 406 may extend centrally along the steering axis 204, between the sensor end 312 and the bearing end 314. As used herein to describe the sealing sensor cover 208, “internal” may indicate a location within the central through-hole 406 and “external” may indicate a location outside of the central through-hole 406.

The sealing sensor cover 208 may further include an external sealing ring 412 comprising one or more ribs. As an example, the external sealing ring 412 may comprise a first external rib 414 and a second external rib 416. The first external rib 414 may be closer to the bearing end 314 than the second external rib 416. The second external rib 416 may be closer to the sensor end 312 than the first external rib 414. The first and second external ribs 414, 416 may be coaxially stacked along the steering axis 204. The external sealing ring 412 may be located at a radially outward facing surface 418. The radially outward facing surface 418 may be a radially outermost surface of the disc portion 404 of the sealing sensor cover 208. The radially outward facing surface 418 may be cylindrical. As such, the one or more ribs of the external sealing ring 412 may be circular. That is, the first and second external ribs 414, 416 may follow a circular pathway around the radially outward facing surface 418. The external sealing ring 412 may be positioned in face-sharing contact with the inner surface 306 of the sensor cavity 304 at the first interface 322 of FIG. 3 when assembled with the steering arm 228 as shown therein. The first external rib 414 and the second external rib 416 may have semicircular cross sectional profiles. In other examples, the cross sectional profiles of the ribs of the sealing rings of the sealing sensor cover 208 may be semioval, or other rounded shape. The first external rib 414 and the second external rib 416 may be identical to each other, in some examples. For example, the semicircular cross sectional profiles may have approximately the same radii. In examples where the external sealing ring 412 includes two or more ribs, the two or more ribs may further have approximately the same diameter measured from the steering axis 204 to the radially outermost point of the ribs.

The sealing sensor cover 208 may further include an internal sealing ring 422 comprising one or more ribs. As an example, the internal sealing ring 422 may include a first internal rib 424 and a second internal rib 426. The first internal rib 424 may be closer to the bearing end 314 than the second internal rib 426. The second internal rib 426 may be closer to the sensor end 312 than the first internal rib 424. The first and second internal ribs 424, 426 may be coaxially stacked along the steering axis 204. The internal sealing ring 422 may be located at a radially inward facing surface 420 of the cylindrical portion 402. The radially inward facing surface 420 may be a cylindrical surface facing radially inward to the steering axis 204. The radially inward facing surface 420 may circumferentially surround the central through-hole 406 such that the radially inward facing surface 420 defines the shape of the central through-hole 406. As such, the one or more ribs of the internal sealing ring 422 may be circular. That is, like the rib(s) of the external sealing ring 412, the rib(s) of the internal sealing ring 422 may follow a circular pathway around the radially inward facing surface 420. The internal sealing ring 422 may be positioned in face-sharing contact with the outer surface 308 of the steering sensor 202 at the second interface 324 of FIG. 3 when assembled with the steering sensor 202 as shown therein. Like the first and second external ribs 414, 416, the first and second internal ribs 424, 426 may have semicircular cross sectional profiles. The first internal rib 424 and the second internal rib 426 may be identical to each other, in some examples. For example, the semicircular cross sectional profiles may have approximately the same radii. In some examples, the radius of the semicircular profiles of the internal ribs may be approximately the same as the radius of the semicircular profiles of the external ribs. In examples where the external sealing ring 412 includes two or more ribs, the two or more ribs may further have approximately the same diameter measured from the steering axis 204 to the radially outermost point of the ribs. The diameter of the rib(s) of the internal sealing ring 422 may be smaller than the diameter of the rib(s) of the external sealing ring 412.

The radially inward facing surface 420 may have various diameters according to the shape of the sensor (e.g., sensor 202 of FIGS. 2 and 3). For example, the radially inward facing surface 420 may include a first portion having a first diameter 442 and a second portion having a second diameter 444. The internal sealing ring 422 may protrude inward from the second portion having the second diameter 444. An axial length 446 of the first portion having the first diameter 442 may be approximately half of an axial length 448 of the sealing sensor cover 208, as an example. Additionally or alternatively, the axial length 446 may be approximately the same as the axial thickness 432. The radially inward facing surface 420 may have a shape corresponding to the outer surface 308 of the steering sensor 202 such that the radially inward facing surface 420 is in face-sharing contact with the outer surface 308 along up to the entirety of the axial length 448. Thus, in examples where the steering sensor 202 is shaped differently than shown in FIG. 3, the radially inward facing surface 420 may have a different corresponding shape than shown in FIG. 4.

Including more than one rib per sealing ring (e.g., internal sealing ring 422 and external sealing ring 412) may increase the effectiveness of the seal formed by that sealing ring such that fluid is less likely to leak through the seal. For example, a two rib sealing ring may form a more effective seal than a single rib sealing ring, analogous to an X-ring (e.g., ring with X-shaped cross section profile) compared to an O-ring (e.g., ring with circular cross sectional profile). That is, the two rib sealing ring may be configured as an integral X-ring, and the single rib sealing ring may be configured as an integral O-ring. However, one or more of the one or more sealing rings of the sealing sensor cover 208 may be a single rib sealing ring. For example, a second internal sealing ring 452 comprises a single internal rib 454 configured to seal to the sensor (e.g., sensor 202 of FIGS. 2 and 3) when positioned within the central through-hole 406. The second internal sealing ring 452 may be positioned along the first portion having the first diameter 442. In some examples, the second internal sealing ring 452 is omitted such that the sealing sensor cover includes one external sealing ring and one internal sealing ring. Further, examples where one or more of the one or more sealing rings includes three or more ribs has been envisioned, as additional ribs may increase seal strength.

Thus, a sealing sensor cover in accordance with the present disclosure may include one or more sealing rings integrally arranged internally and/or externally, and each of the sealing rings may include one or more ribs (e.g., according to a desired seal strength, type of flexible material, etc.). As noted above, internal sealing rings (e.g., internally arranged sealing rings) may be positioned within the central through-hole 406 (e.g., on the radially inward facing surface 420 which circumferentially surrounds and defines the central through-hole 406), and external sealing rings (e.g., externally arranged sealing rings) may be positioned outside of the central through-hole 406. External sealing rings such as the external sealing ring 412 may be positioned on a radially facing surface such as radially outward facing surface 418, on an axially facing surface such as the bearing side surface 436, on an angled surface facing neither axially nor radially such as the sensor side surface 438, or a combination of radial, axial, and/or angled surfaces. Likewise, internal sealing rings may be positioned on radial, axial, and/or angled surfaces within the central through-hole without departing from the scope of the present disclosure. For example, to fit with a sensor having diametrically tapering geometry, the diameter of the central through-hole 406 may vary axially gradually such that an internal sealing ring is positioned on an internal angled surface. Additionally or alternatively, an internal sealing ring may be positioned on an axially facing surface of a ledge 430 where the diameter of the radially inward facing surface 420 abruptly changes (e.g., from the first diameter 442 to the second diameter 444 as shown).

Turning to FIG. 5, a perspective view 500 of the sealing sensor cover 208 is shown. For reference, the cross sectional view 400 of FIG. 4 may be a view of a section taken along segment A-A’ shown in FIG. 5.

The surface features 450 of the bearing side surface 436 may include recesses 502 divided by radially arranged protrusions 504. The protrusions 504 may extend from the cylindrical portion 402 radially outward, towards the external sealing ring 412. There may be six of the protrusions 504, as shown. However, in other examples, there may be more or fewer than six. The protrusions 504 may include indents 506. The indents 506 may be proximate to the external sealing ring 412, compared to the second internal sealing ring 452. The indents 506 may be rounded cut-outs from the protrusions 504.

The recesses 502 interposed between the protrusions 504 may be shaped as annular segments. The protrusions 504 may be uniformly arranged around the cylindrical portion 402 such that the recesses 502 are substantially identical. The recesses 502 may have bottom surfaces 508 parallel with the sensor side surface 438. In this way, the bottom surfaces 508 may not be at a non-zero angle with each of the x, y, and z-axes. Further, a depth 510, or a distance between a top of the cylindrical portion 402 and the bottom surface 508, of the recesses 502 may increase radially inward. The surface features 450 may be arranged otherwise so as to position the bearing side surface 436 in face-sharing contact with the kingpin housing 326 of FIG. 3.

Turning to FIG. 6, a method 600 is shown for assembling a steering system comprising a sealing sensor cover in accordance with the present disclosure, such as the sealing sensor cover 208 of FIGS. 2-5. The steering system may be included in a vehicle such as the vehicle 100 of FIG. 1. The method 600 may be performed manually and/or via an automated assembly line.

At 602, the method 600 includes positioning a sensor in a sensor cavity. The sensor cavity may be an opening in a steering arm adapted to receive the sensor (e.g., steering sensor). The steering arm may be actuated via rotation of a steering wheel mechanically coupled to the steering arm to adjust a steering angle of a wheels of the vehicle. As such, the sensor may be a steering sensor configured to detect the steering angle.

At 604, the method 600 includes sealing the sensor cavity via one or more sealing rings integral with the sealing sensor cover such that lubricant fluid in a bearing positioned outside of the sensor cavity is sealed from the sensor cavity. The bearing may be a kingpin bearing about which a knuckle and the steering arm comprising the sensor cavity rotate relative to one another. The sealing sensor cover may be constructed of a flexible material, such as rubber, silicone, elastomeric plastic, etc. The one or more integral sealing rings may each comprise one or more ribs protruding integrally from a surface of the sealing sensor cover. The ribs may have semicircular or other rounded cross sectional profile so as to function as an integral O-ring when pressed against a surface (e.g., of the sensor and/or the sensor cavity).

In at least some examples, 604 includes 606. At 606, the method 600 includes forming a first seal at a first interface between the sealing sensor cover and an inner surface of the sensor cavity of the steering arm via an external sealing ring of the one or more sealing rings, which are integral with the sealing sensor cover. The external sealing ring may include one or more ribs extending radially outward from an exterior surface (e.g., surface outside of a central through-hole such as central through-hole 406 of FIGS. 4 and 5) of the sealing sensor cover. The exterior surface may be a radially outermost surface. The exterior surface may be cylindrical such that the ribs are circular. There may be one or more external sealing rings included in the sealing sensor cover, each including one or more ribs. Forming the first seal may include pressing the rib(s) of the external sealing ring on the inner surface of the sensor cavity. The dimensions of the sealing sensor cover may be sized such that the rib(s) of the external sealing ring are pressed against the inner surface with sufficient pressure to form the first seal when the sealing sensor cover is positioned with the rib(s) in face-sharing contact with the inner surface. For example, the diameter of the exterior surface may be slightly less than the diameter of the inner surface, for example, by a difference that is less than the distance whereby the rib(s) protrude from the exterior surface. In this way, pressure between the rib(s) integrally arranged on the exterior surface of the sealing sensor cover and the inner surface of the sensor cavity may form the first seal, preventing fluid from crossing the first interface and flowing into the sensor cavity.

In at least some examples, 604 includes 608. At 608, the method 600 includes forming a second seal at a second interface between the sealing sensor cover and an outer surface of the sensor via an internal sealing ring of the one or more sealing rings, which are integral with the sealing sensor cover. The internal sealing ring may include one or more ribs extending radially outward from an internal surface of the sealing sensor cover. The internal surface may define a boundary of the central through-hole. That is, the internal surface may circumferentially surround and face in toward the central through-hole. The interior surface may be cylindrical, conical, or the like, such that the ribs are circular. There may be one or more internal sealing rings included in the sealing sensor cover, each including one or more ribs. Similar to the first seal, forming the second seal may include pressing the rib(s) of the internal sealing ring on the outer surface of the sensor. The dimensions of the sealing sensor cover may be sized such that the rib(s) of the internal sealing ring are pressed against the outer surface with sufficient pressure to form the second seal when the sealing sensor cover is positioned with the rib(s) in face-sharing contact with the outer surface. For example, the diameter of the interior surface may be slightly less than the diameter of the outer surface, for example, by a difference that is less than the distance whereby the rib(s) protrude from the interior surface. In this way, pressure between the rib(s) integrally arranged on the interior surface of the sealing sensor cover and the outer surface of the sensor may form the second seal, preventing fluid from crossing the second interface and flowing into the sensor cavity.

By performing the method 600 to position the sealing sensor cover between the sensor and the bearing, the lubricant fluid of the bearing is sealed out of the sensor cavity wherein the sensor is positioned such that lubricant fluid is retained in the bearing. Therefore, effects of lubricant loss, such as degradation to the bearing and reduced steering capability, may not be experienced. Further, the method 600 may be performed without including any O-rings, or other sealing components for forming the first and second seals. That is, due to the integral sealing rings of the sealing sensor cover, the first and second seals may be formed between the sealing sensor cover and the surfaces of the sensor and sensor cavity without additional components (e.g., O-rings not integrally formed with the sealing sensor cover).

Turning to FIG. 7, a method 700 is shown for operating a steering system comprising a sealing sensor cover in accordance with the present disclosure. The method 700 may be stored as instructions in non-volatile memory of a controller of a system (e.g., vehicle) comprising the steering system. For example, the method 700 may be stored as executable instructions in non-volatile memory of the controller 112 of the vehicle 100 comprising the steering system 102 as shown schematically in FIG. 1. The steering system 102 may include a sealing sensor cover, such as the sealing sensor cover 208 of FIGS. 2-5.

The method 700 begins at 702. At 702, the method 700 includes actuating a steering arm (e.g., steering arm 228 of FIGS. 2 and 3) comprising a sensor cavity (e.g., sensor cavity 304 of FIG. 3) wherein a steering sensor (e.g., sensor 202 of FIGS. 2 and 3) is positioned and sealed from a bearing (e.g., kingpin bearing 212 of FIGS. 2 and 3) via a sealing sensor cover (e.g., sealing sensor cover 208 of FIGS. 2-5) including integral sealing rings (e.g., internal and/or external sealing rings integral with the sealing sensor cover such as internal sealing ring 422, second internal sealing ring 452, and external sealing ring 412). The controller may send a command signal to actuate the steering arm. Alternatively, the steering arm may be actuated manually, for example, via manual rotation of a steering wheel mechanically coupled to the steering arm (e.g., via a steering column). Actuating the steering arm may rotate a knuckle (e.g., knuckle 216 of FIGS. 2 and 3) coupled to the steering arm via a kingpin bearing (e.g., kingpin bearing 212 of FIGS. 2 and 3) about a steering axis (e.g., steering axis 204 of FIGS. 2-5) extending centrally through a pin (e.g., kingpin 206 of FIGS. 2 and 3) of the bearing and the steering sensor. The knuckle may be mechanically coupled to a wheel hub (e.g., wheel hub 224 of FIG. 2). Therefore, a wheel fixed to the wheel hub may rotate around the steering axis along with the knuckle according to actuation of the steering arm, thereby steering the vehicle.

The method 700 proceeds to 704. At 704, the method 700 includes detecting a steering angle via the steering sensor. The steering angle may be a measure of the rotation (e.g., angular position) of the knuckle relative to the steering arm about the steering axis. Detecting the steering angle may include monitoring the steering angle over a period up to a full length of duration of operation. For example, detecting the steering angle may include the steering sensor automatically sending an electrical signal to the controller indicating the steering angle (e.g., according to pulse width) based on a position of the steering sensor. The position of the steering sensor may change (e.g., along an arc pathway) during rotation of the knuckle relative to the steering arm. The position of the steering sensor, which is related to the steering angle, may be measured by various means according to the type of sensor. For example, the sensor may be a magnetic sensor where a voltage is induced by a magnetic field of a magnet positioned on a different component than the steering arm. The magnetic field strength as experienced by the sensor may vary as a distance between the sensor and the magnet is adjusted according to actuation of the steering arm, and consequential rotation of the knuckle and the wheel around the steering axis. Non-magnetic sensors, such as optical encoders, are also possible without departing from the scope of the present disclosure.

The method 700 returns. The steps of the method 700 may be repeated throughout operation of the steering system (e.g., steering of the vehicle).

The technical effect of the sealing sensor cover disclosed herein is to prevent lubricant fluid of a kingpin bearing from leaking out of the bearing and into a sensor cavity where a sensor is positioned. By sealing interfaces between the kingpin bearing and the sensor cavity, degradation to the kingpin bearing resulting from lubricant loss may be reduced (e.g., avoided). Further, degradation to the sensor and/or effect on an ability of the sensor to detect the steering angle may be reduced by the sealing sensor cover preventing contact with the lubricant fluid. Moreover, the one or more sealing rings being integral with the sealing sensor cover may reduce complexity by reducing both a number of parts (e.g., not including any O-rings) and difficulty of manufacturing (e.g., reducing demanded precision of machining), compared to previous seals between a kingpin bearing and a sensor.

The disclosure also provides support for a steering system, comprising: a sealing sensor cover arranged between a sensor and a kingpin bearing, and one or more sealing rings integral with the sealing sensor cover. In a first example of the system, the sealing sensor cover is constructed of a flexible material. In a second example of the system, optionally including the first example, the sensor is positioned in a sensor cavity of a steering arm and the sealing sensor cover is configured to seal the sensor cavity from lubricant fluid of the kingpin bearing. In a third example of the system, optionally including one or both of the first and second examples, the one or more sealing rings include an external sealing ring on a radially outward facing surface of the sealing sensor cover. In a fourth example of the system, optionally including one or more or each of the first through third examples, the one or more sealing rings include an internal sealing ring on a radially inward facing surface of the sealing sensor cover. In a fifth example of the system, optionally including one or more or each of the first through fourth examples, each of the one or more sealing rings includes one or more ribs arranged coaxially. In a sixth example of the system, optionally including one or more or each of the first through fifth examples, the one or more ribs have a semicircular cross sectional profile.

The disclosure also provides support for a sealing sensor cover, comprising: a central through-hole configured to receive a sensor, an external sealing ring integral with the sealing sensor cover and configured to seal a first interface between the sealing sensor cover and an inner surface of a sensor cavity where the sensor is positioned, and an internal sealing ring integral with the sealing sensor cover and configured to seal a second interface between the sealing sensor cover and the sensor. In a first example of the system, the sealing sensor cover is constructed of a flexible material. In a second example of the system, optionally including the first example, the internal sealing ring is positioned on a radially inward facing surface of the sealing sensor cover circumferentially surrounding the central through-hole. In a third example of the system, optionally including one or both of the first and second examples, the external sealing ring is positioned on a radially outward facing surface of the sealing sensor cover. In a fourth example of the system, optionally including one or more or each of the first through third examples, the sealing sensor cover includes a cylindrical portion and a disc portion protruding radially outward therefrom, and the central through-hole extends centrally through both the cylindrical portion and the disc portion. In a fifth example of the system, optionally including one or more or each of the first through fourth examples, the disc portion is tapered. In a sixth example of the system, optionally including one or more or each of the first through fifth examples, the disc portion includes recesses separated by radially arranged protrusions having indents. In a seventh example of the system, optionally including one or more or each of the first through sixth examples, the sealing sensor cover is included in a steering system of a vehicle and the sensor is a steering sensor.

The disclosure also provides support for a method, comprising: actuating a steering arm comprising a sensor cavity wherein a steering sensor is positioned and sealed from lubricant fluid of a kingpin bearing via a sealing sensor cover having integral sealing rings, and detecting a steering angle via the steering sensor. In a first example of the method, actuating the steering arm comprises rotating a steering wheel to rotate a knuckle, coupled to the steering arm via the kingpin bearing, about a steering axis. In a second example of the method, optionally including the first example, the steering angle is a measure of rotation of the knuckle relative to the steering arm about the steering axis. In a third example of the method, optionally including one or both of the first and second examples, the integral sealing rings of the sealing sensor cover include an internal sealing ring in face-sharing contact with an outer surface of the steering sensor and an external sealing ring in face-sharing contact with an inner surface of the sensor cavity. In a fourth example of the method, optionally including one or more or each of the first through third examples, the integral sealing rings of the sealing sensor cover each include one or more coaxial ribs having a semicircular cross sectional profile.

FIGS. 1-5 show example configurations with approximate position. FIGS. 4 and 5 are shown approximately to scale; though other relative dimensions may be used. As used herein, the term “approximately” is construed to mean plus or minus five percent of the range unless otherwise specified.

If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. Moreover, the components may be described as they relate to reference axes included in the drawings.

Features described as axial may be approximately parallel with an axis referenced unless otherwise specified. Features described as counter-axial may be approximately perpendicular to the axis referenced unless otherwise specified. Features described as radial may circumferentially surround or extend outward from an axis, such as the axis referenced, or a component or feature described prior as being radial to a referenced axis, unless otherwise specified.

Features described as longitudinal may be approximately parallel with an axis that is longitudinal. A lateral axis may be normal to a longitudinal axis and a vertical axis. Features described as lateral may be approximately parallel with the lateral axis. A vertical axis may be normal to a lateral axis and a longitudinal axis. Features described as vertical may be approximately parallel with a vertical axis.

It will be appreciated that the configurations and routines disclosed herein are exemplary in nature, and that these specific embodiments are not to be considered in a limiting sense, because numerous variations are possible. Moreover, unless explicitly stated to the contrary, the terms “first,” “second,” “third,” and the like are not intended to denote any order, position, quantity, or importance, but rather are used merely as labels to distinguish one element from another. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A steering system, comprising:
a sealing sensor cover arranged between a sensor and a kingpin bearing; and
one or more sealing rings integral with the sealing sensor cover.

2. The steering system of claim 1, wherein the sealing sensor cover is constructed of a flexible material.

3. The steering system of claim 1, wherein the sensor is positioned in a sensor cavity of a steering arm and the sealing sensor cover is configured to seal the sensor cavity from lubricant fluid of the kingpin bearing.

4. The steering system of claim 1, wherein the one or more sealing rings include an external sealing ring on a radially outward facing surface of the sealing sensor cover.

5. The steering system of claim 1, wherein the one or more sealing rings include an internal sealing ring on a radially inward facing surface of the sealing sensor cover.

6. The steering system of claim 1, wherein each of the one or more sealing rings includes one or more ribs arranged coaxially.

7. The steering system of claim 6, wherein the one or more ribs have a semicircular cross sectional profile.

8. A sealing sensor cover, comprising:
a central through-hole configured to receive a sensor;
an external sealing ring integral with the sealing sensor cover and configured to seal a first interface between the sealing sensor cover and an inner surface of a sensor cavity where the sensor is positioned; and
an internal sealing ring integral with the sealing sensor cover and configured to seal a second interface between the sealing sensor cover and the sensor.

9. The sealing sensor cover of claim 8, wherein the sealing sensor cover is constructed of a flexible material.

10. The sealing sensor cover of claim 8, wherein the internal sealing ring is positioned on a radially inward facing surface of the sealing sensor cover circumferentially surrounding the central through-hole.

11. The sealing sensor cover of claim 8, wherein the external sealing ring is positioned on a radially outward facing surface of the sealing sensor cover.

12. The sealing sensor cover of claim 8, wherein the sealing sensor cover includes a cylindrical portion and a disc portion protruding radially outward therefrom, and the central through-hole extends centrally through both the cylindrical portion and the disc portion.

13. The sealing sensor cover of claim 12, wherein the disc portion is tapered.

14. The sealing sensor cover of claim 12, wherein the disc portion includes recesses separated by radially arranged protrusions having indents.

15. The sealing sensor cover of claim 8, wherein the sealing sensor cover is included in a steering system of a vehicle and the sensor is a steering sensor.

16. A method, comprising:
actuating a steering arm comprising a sensor cavity wherein a steering sensor is positioned and sealed from lubricant fluid of a kingpin bearing via a sealing sensor cover having integral sealing rings; and
detecting a steering angle via the steering sensor.

17. The method of claim 16, wherein actuating the steering arm comprises rotating a steering wheel to rotate a knuckle, coupled to the steering arm via the kingpin bearing, about a steering axis.

18. The method of claim 17, wherein the steering angle is a measure of rotation of the knuckle relative to the steering arm about the steering axis.

19. The method of claim 16, wherein the integral sealing rings of the sealing sensor cover include an internal sealing ring in face-sharing contact with an outer surface of the steering sensor and an external sealing ring in face-sharing contact with an inner surface of the sensor cavity.

20. The method of claim 16, wherein the integral sealing rings of the sealing sensor cover each include one or more coaxial ribs having a semicircular cross sectional profile.
